(19) United States
(12) Patent Application Publication
(10) Pub. No.: US 2024/0168375 A1
(43) Pub. Date: May 23, 2024

(54) SEMICONDUCTOR PHOTORESIST COMPOSITION AND METHOD OF FORMING PATTERS USING THE COMPOSITION

(71) Applicant: SAMSUNG SDI CO., LTD., Yongin-si (KR)

(72) Inventors: Minyoung LEE, Suwon-si (KR); Seung HAN, Suwon-si (KR); Sangkyun IM, Suwon-si (KR); Jimin KIM, Suwon-si (KR); Yaeun SEO, Suwon-si (KR); Gyeong Ryeong BAK, Suwon-si (KR)

(21) Appl. No.: 18/484,313

(22) Filed: Oct. 10, 2023

(30) Foreign Application Priority Data
Nov. 3, 2022 (KR) 10-2022-0145387

(51) Int. Cl. G03F 7/004; C07F 7/22

(52) U.S. Cl. CPC G03F 7/0044; C07F 7/2224

(57) ABSTRACT

A semiconductor photoresist composition including an organometallic compound, an additive represented by Chemical Formula 1, and a solvent, and a method of forming uses the semiconductor photoresist composition. Details of Chemical Formula 1 are as defined in the specification.

### CROSS-REFERENCE TO RELATED APPLICATION

This application claims priority to and the benefit of Korean Patent Application No. 10-2022-0145387, filed in the Korean Intellectual Property Office on Nov. 3, 2022, the entire content of which is incorporated herein by reference.

### BACKGROUND

### 1. Field

Embodiments of the present disclosure described herein are related to a semiconductor photoresist composition and a method for forming patterns utilizing the same.

### 2. Description of the Related Art

Extreme ultraviolet (EUV) lithography is receiving attention as one essential or suitable technology for manufacturing a next generation semiconductor device. The EUV lithography is a pattern-forming technology utilizing an EUV ray having a wavelength of about 13.5 nm as an exposure light source. According to the EUV lithography, an extremely fine pattern (e.g., less than or equal to about 20 nm) may be formed in an exposure process during a manufacture of a semiconductor device.

The extreme ultraviolet (EUV) lithography is realized through development of compatible photoresists which can be performed at a spatial resolution of less than or equal to about 16 nm. Currently, efforts to overcome insufficient specifications of related art chemically amplified (CA) photoresists, such as resolution, photospeed, and/or a feature roughness (or also referred to as a line edge roughness or LER for the next generation device are being made).

An intrinsic image blurring due to an acid catalyzed reaction in these polymer-type photoresists limits the resolution in small feature sizes, which is suitable in electron beam (e-beam) lithography. The chemically amplified (CA) photoresists are designed for high sensitivity, but because their typical elemental makeups reduce light absorbance of the photoresists at a wavelength of about 13.5 nm and thus decrease their sensitivity, the chemically amplified (CA) photoresists may partially have more difficulties under an EUV exposure.

The CA photoresists may have difficulties in the small feature sizes due to roughness issues, and have increased line edge roughness (LER) as the photospeed is decreased partially due to inherited characteristics (e.g., essence) of acid catalyst processes. Accordingly, a novel high-performance photoresist is desired (e.g., required) in the semiconductor industry because of these defects and problems of the CA photoresists.

In order to overcome the aforementioned drawbacks of the chemically amplified (CA) organic photosensitive composition, an inorganic photosensitive composition has been envisioned and/or researched. The inorganic photosensitive composition is mainly utilized for negative tone patterning having resistance against removal by a developer composition due to chemical modification through nonchemical amplification mechanism. The inorganic composition contains an inorganic element having a higher EUV absorption rate than hydrocarbons and thus may secure sensitivity through the nonchemical amplification mechanism and in addition, is less sensitive about a stochastic effect and thus suitable for having low line edge roughness and for having a smaller number of defects.

Inorganic photoresists based on peroxopolyacids of tungsten mixed with niobium, titanium, and/or tantalum have been reported as radiation sensitive materials for patterning

These materials are effective for patterning large pitches for bilayer configuration as far ultraviolet (deep UV), X-ray, and electron beam sources. More recently, when cationic hafnium metal oxide sulfate (HfSOx) materials along with a peroxo complexing agent has been utilized to image a 15 nm half-pitch (HP) through projection EUV exposure, impressive performance has been obtained. This system exhibits the highest performance of a non-CA photoresist and has a practicable photospeed close to the requirement for an EUV photoresist. However, the hafnium metal oxide sulfate materials having the peroxo complexing agent have a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of about 25 wt % and/or the like.

### SUMMARY

Aspects of embodiments are directed toward a semiconductor photoresist composition having excellent or suitable coating properties, sensitivity, and pattern-forming abilities.

Aspects of embodiments are directed toward a method of forming patterns utilizing the semiconductor photoresist composition.

Additional aspects will be set forth in part in the description which follows and, in part, will be apparent from the description, or may be learned by practice of the presented embodiments of the disclosure.

Recently, active research has been conducted as it is suitable for molecules containing tin, which may have excellent or suitable absorption of extreme ultraviolet rays. As for an organotin polymer, alkyl ligands are dissociated by light absorption or secondary electrons produced thereby, and are cross-linked with adjacent chains through oxo bonds and thus enable the negative tone patterning which may not be removed by an organic developing solution. This organotin polymer exhibits greatly improved sensitivity as well as maintaining a resolution and line edge roughness, but the patterning characteristics need to be additionally improved for commercial application (e.g., availability).

A semiconductor photoresist composition according to an embodiment includes an organometallic compound, an additive represented by Chemical Formula 1, and a solvent.

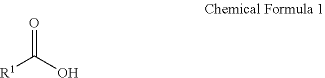

In Chemical Formula 1,

R¹ may be a C1 to C7 alkyl group substituted with at least one halogen, a C3 to C10 cycloalkyl group substituted with at least one halogen, a C6 to C20 aryl group substituted with at least one halogen, or a C1 to C7 haloalkyl group substituted with at least one of a C1 to C5 alkyl group substituted with at least one halogen, a C3 to C10 cycloalkyl group substituted with at least one C1 to C5 haloalkyl group substituted with at least one halogen, a C6 to C20 aryl group substituted with at least one C1 to C5 haloalkyl group substituted with at least one halogen, or a combination thereof.

In an embodiment, R¹ may be a C1 to C7 alkyl group substituted with 1 to 3 halogens, a C3 to C10 cycloalkyl group substituted with 1 to 3 halogens, a C6 to C20 aryl group substituted with 1 to 3 halogens, a C1 to C7 alkyl group substituted with C1 to C5 haloalkyl group substituted with 1 to 3 halogens, a C3 to C10 cycloalkyl group substituted with a C1 to C5 haloalkyl group substituted with 1 to 3 halogens, a C6 to C20 aryl group substituted with a C1 to C5 haloalkyl group substituted with 1 to 3 halogens, or a combination thereof.

In an embodiment, R¹ may be a C1 to C7 alkyl group substituted with at least one of fluoro (—F), iodo (—I), a C1 to C5 fluoroalkyl group, or a C1 to C5 iodoalkyl group, a C3 to C10 cycloalkyl group substituted with at least one of fluoro (—F), iodo (—I), a C1 to C5 fluoroalkyl group, or a C1 to C5 iodoalkyl group, a C6 to C20 aryl group substituted with at least one of fluoro (—F), iodo (—I), a C1 to C5 fluoroalkyl group, or a C1 to C5 iodoalkyl group, or a combination thereof.

In an embodiment, R¹ may be a C1 to C3 alkyl group substituted with at least one of fluoro (—F), iodo (—I), a fluoromethyl group, or an iodomethyl group, a C3 to C6 cycloalkyl group substituted with at least one of fluoro (—F), iodo (—I), a fluoromethyl group, or an iodomethyl group, a C6 to C12 aryl group substituted with at least one of fluoro (—F), iodo (—I), a fluoromethyl group, or an iodomethyl group, or a combination thereof.

In an embodiment, R¹ may be a fluoromethyl group, a difluoromethyl group, a trifluoromethyl group, a 1-fluoroethyl group, a 2-fluoroethyl group, a 1,1-difluoroethyl group, a 2,2-difluoroethyl group, a 1,2-difluoroethyl group, 1,1,2-trifluoroethyl group, a 1,2,2-trifluoroethyl group, an iodomethyl group, a diiodomethyl group, a triiodomethyl group, a 1-iodoethyl group, a 2-iodoethyl group, a 1,1-diiodoethyl group, a 2,2-diiodoethyl group, a 1,2-diiodoethyl group, a 1,1,2-triiodoethyl group, a 1,2,2-triiodoethyl group, a fluoroiodomethyl group, a fluorophenyl group, a difluorophenyl group, a trifluorophenyl group, an iodophenyl group, a diodophenyl group, a triiodophenyl group, a fluoromethylphenyl group, a difluoromethylphenyl group, a trifluoromethylphenyl group, an iodomethylphenyl group, a diiodomethylphenyl group, or a triiodomethylphenyl group.

In an embodiment, the additive represented by Chemical Formula 1 may be selected from compounds listed in Group 1.

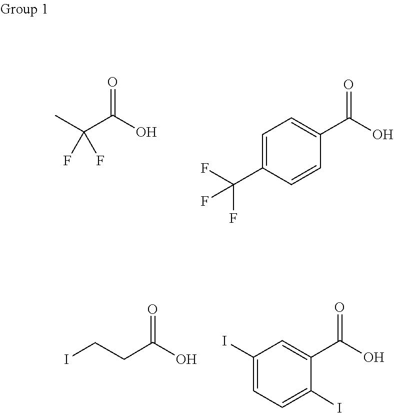

In an embodiment, the additive may be included in an amount of about 0.5 wt % to about 10 wt %.

In an embodiment, the organometallic compound may be an organotin compound.

In an embodiment, the organotin compound may include at least one of an alkyl tin oxo group and an alkyl tin carboxyl group.

In an embodiment, the organotin compound may be represented by Chemical Formula 2.

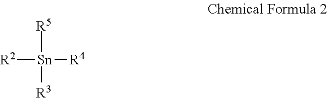

In Chemical Formula 2,

In an embodiment, R² may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein Ra is a substituted or unsubstituted C1 to C20 alkylene group and R^{b} is a substituted or unsubstituted C1 to C20 alkyl group),

In an embodiment, R³ to R⁵ may each independently be —OR^{c} or —OC(═O)R^{d},

In an embodiment, R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

In an embodiment, Rd may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In an embodiment, the semiconductor photoresist composition may further include at least one of an organotin compound represented by Chemical Formula 3 and an organotin compound represented by Chemical Formula 4.

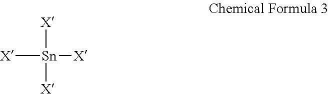

In Chemical Formula 3,

In an embodiment, X′ is —OR⁶ or —OC(═O)R⁷,

In an embodiment, R⁶ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

In an embodiment, R⁷ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;

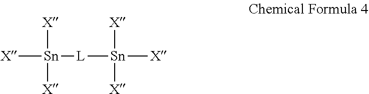

wherein, in Chemical Formula 4,

In an embodiment, X″ may be —OR⁸ or —OC(═O)R⁹,

In an embodiment, R⁸ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,

In an embodiment, Ro may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

In an embodiment, L may be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group having at least one double bond or triple bond, a substituted or unsubstituted divalent C6 to C20 aromatic hydrocarbon group, —O—, —C(═O)—, or a combination thereof.

In an embodiment, a total amount of the organotin compound represented by Chemical Formula 3 and the organotin compound represented by Chemical Formula 4, and the organotin compound represented by Chemical Formula 2 may be included in a weight ratio of about 1:1 to about 1:20.

In an embodiment, the organotin compound represented by Chemical Formula 2 may be represented by at least one of Chemical Formula 5 to Chemical Formula 8.

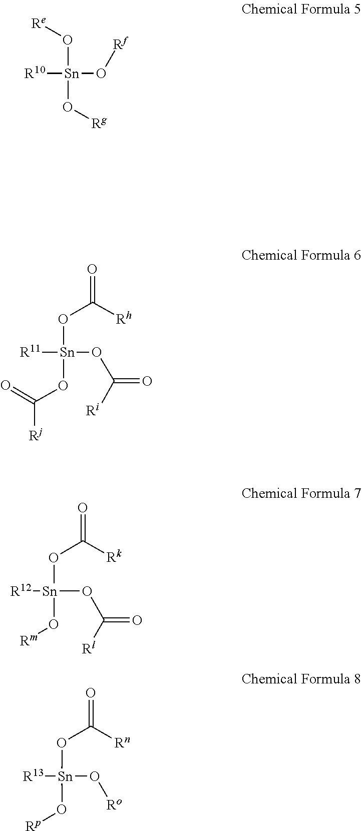

In Chemical Formula 5 to Chemical Formula 8,

R¹⁰ to R¹³ may each independently be a substituted or unsubstituted C1 to C20 alkyl group, a substituted or unsubstituted C3 to C20 cycloalkyl group, a substituted or unsubstituted C2 to C20 aliphatic unsaturated organic group having at least one double bond or triple bond, a substituted or unsubstituted C6 to C30 aryl group, an ethoxy group, a propoxy group, or a combination thereof,

In an embodiment, R^{e}, R^{f}, R^{g}, R^{m}, R^{o}, and R^{p} may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

In an embodiment, R^{h}, Rⁱ, R^{j}, R^{k}, R^{l}, and Rⁿ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In an embodiment, the semiconductor photoresist composition may further include an additive of a surfactant, a crosslinking agent, a leveling agent, or a combination thereof.

The method of forming patterns according to an embodiment includes forming an etching-objective layer on a substrate, coating the semiconductor photoresist composition on the etching-objective layer to form a photoresist layer, patterning the photoresist layer to form a photoresist pattern, and etching the etching-objective layer utilizing the photoresist pattern as an etching mask.

In an embodiment, the photoresist pattern may be formed utilizing light in a wavelength of about 5 nm to about 150 nm.

In an embodiment, the method of forming patterns may further include providing a resist underlayer formed between the substrate and the photoresist layer.

In an embodiment, the photoresist pattern may have a width of about 5 nm to about 100 nm.

Because the semiconductor photoresist composition according to an embodiment has relatively excellent or suitable resolution and sensitivity, it is possible to provide a photoresist pattern in which the pattern has excellent or suitable limit resolution and does not collapse even when the pattern has a high aspect ratio.

### BRIEF DESCRIPTION OF THE DRAWINGS

FIGS. 1-5 are cross-sectional views for explaining a method of forming patterns utilizing a semiconductor photoresist composition according to an embodiment.

### DETAILED DESCRIPTION

Hereinafter, referring to the drawings, embodiments of the present disclosure are described in more detail. In the following description of the present disclosure, some-suitable functions or constructions may not be described in order to clarify the present disclosure.

In order to clearly illustrate the present disclosure, the description and relationships are omitted, and throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, etc., are exaggerated for clarity. In the drawings, the thickness of a part of layers or regions, etc., is exaggerated for clarity. It will be understood that when an element such as a layer, film, region, or substrate is referred to as being “on” another element, it can be directly on the other element or intervening elements may also be present.

It will be understood that, although the terms “first”, “second”, and/or the like may be utilized herein to describe one or more suitable elements, these elements should not be limited by these terms. These terms are only utilized to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise.

In some embodiments, terms such as “below,” “lower,” “above,” “upper,” and/or the like are utilized to describe the relationship of the configurations shown in the drawings. The terms are utilized as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As used herein, the term “substantially,” “about,” and similar terms are used as terms of approximation and not as terms of degree, and are intended to account for the inherent deviations in measured or calculated values that would be recognized by those of ordinary skill in the art. “About” or “substantially”, as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “substantially” may mean within one or more standard deviations, or within +30%, 20%, 10%, 5% of the stated value.

Depending on context, a divalent group may refer or be a polyvalent group (e.g., trivalent, tetravalent, etc., and not just divalent) per, e.g., the structure of a formula in connection with which of the terms are utilized.

As used herein, the term “or” is not to be construed as an exclusive meaning, for example, “A or B” is construed to include A, B, A+B, and/or the like. Hereinafter, the term “combination” includes a mixture of two or more, a

composite of two or more, a copolymer of two or more, an alloy of two or more, a blend of two or more, mutual substitution, and a laminated structure of two or more.

As used herein, the singular forms “a”, “an” and “the” are intended to include the plural forms as well, unless the context clearly indicates otherwise.

In addition, the term “layer” as used herein includes not only a shape formed on the whole surface when viewed from a plan view, but also a shape formed on a partial surface.

As utilized herein, “substituted” refers to replacement of a hydrogen atom by deuterium, a halogen, a hydroxy group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof. “Unsubstituted” refers to non-replacement of a hydrogen atom by another substituent and remaining of the hydrogen atom.

As utilized herein, when a definition is not otherwise provided, “an alkyl group” refers to a linear or branched aliphatic hydrocarbon group. The alkyl group may be “a saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As utilized herein, when a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As utilized herein, “aliphatic unsaturated organic group” refers to a hydrocarbon group including a bond in which the bond between the carbon and carbon atom in the molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As utilized herein, “aryl group” refers to a substituent in which all atoms in the cyclic substituent have a p-orbital and these p-orbitals are conjugated and may include a monocyclic or fused ring polycyclic (i.e., rings sharing adjacent pairs of carbon atoms) functional group.

As utilized herein, “heteroaryl group” refers to an aryl group including at least one heteroatom selected from N, O, S, P, and Si. Two or more heteroaryl groups are linked by a sigma bond directly, or when the heteroaryl group includes two or more rings, the two or more rings may be fused. When the heteroaryl group is a fused ring, each ring may include one to three heteroatoms.

As utilized herein, unless otherwise defined, “alkenyl group” refers to an aliphatic unsaturated alkenyl group including at least one double bond as a linear or branched aliphatic hydrocarbon group.

As utilized herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to an embodiment is described in more detail.

The semiconductor photoresist composition according to an embodiment of the present disclosure includes an organometallic compound, an additive, and a solvent, wherein the additive is represented by Chemical Formula 1.

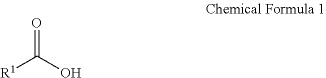

In Chemical Formula 1,

R¹ is a C1 to C12 alkyl group substituted with at least one halogen, a C3 to C10 cycloalkyl group substituted with at least one halogen, a C6 to C20 aryl group substituted with at least one halogen, a C3 to C10 cycloalkyl group substituted with at least one C1 to C5 haloalkyl group substituted with at least one halogen, a C6 to C20 aryl group substituted with at least one C1 to C5 haloalkyl group substituted with at least one halogen, or a combination thereof.

The additive represented by Chemical Formula 1 is a halogen-substituted acid compound that strongly absorbs extreme ultraviolet light, and a semiconductor photoresist composition including the additive may form a pattern even with a small amount of light, thereby improving sensitivity.

The halogen may refer to fluoro (—F), chloro (—Cl), bromo —Br), or iodo (—I).

The C1 to C5 haloalkyl group may refer to a C1 to C5 alkyl group substituted with at least one halogen.

For example, the C1 to C5 haloalkyl group may refer to a C1 to C5 alkyl group substituted with one or more of fluoro (—F), chloro (—Cl), bromo —Br), and iodo (—I).

More specifically, the C1 to C5 haloalkyl group may refer to a C1 to C5 alkyl group substituted with at least one of fluoro (—F) and iodo (—I).

More specifically, the C1 to C5 haloalkyl group may refer to a C1 to C5 alkyl group substituted with 1 to 3 substituents selected from fluoro (—F) and iodo (—I).

For example, R¹ may be a C1 to C12 alkyl group substituted with 1 to 3 halogens, a C3 to C10 cycloalkyl group substituted with 1 to 3 halogens, a C6 to C20 aryl group substituted with 1 to 3 halogens, a C3 to C10 cycloalkyl group substituted with a C1 to C5 haloalkyl group substituted with 1 to 3 halogens, a C6 to C20 aryl group substituted with a C1 to C5 haloalkyl group substituted with 1 to 3 halogens, or a combination thereof.

As a specific example, R¹ may be a C1 to C7 alkyl group substituted with at least one of fluoro (—F), iodo (—I), a C1 to C5 fluoroalkyl group, or a C1 to C5 iodoalkyl group, a C3 to C10 cycloalkyl group substituted with at least one of fluoro (—F), iodo (—I), a C1 to C5 fluoroalkyl group, or a C1 to C5 iodoalkyl group, a C6 to C20 aryl group substituted with at least one of fluoro (—F), iodo (—I), a C1 to C5 fluoroalkyl group, or a C1 to C5 iodoalkyl group, or a combination thereof.

For example, R¹ may be a C1 to C3 alkyl group substituted with at least one of fluoro (—F), iodo (—I), a fluoromethyl group, or an iodomethyl group, a C3 to C6 cycloalkyl group substituted with at least one of fluoro (—F), iodo (—I), a fluoromethyl group, or an iodomethyl group, a C6 to C12 aryl group substituted with at least one of fluoro (—F), iodo (—I), a fluoromethyl group, or an iodomethyl group, or a combination thereof.

In particular, when R¹ is an alkyl group and the number of carbon atoms of the alkyl group is 3 or less, it may be more advantageous in terms of reducing defects that may occur in the pattern after exposure.

For example, when R¹ is an alkyl group, desirably R¹ is a C1 to C3 alkyl group substituted with at least one halogen, specifically, R¹ is a C1 to C3 alkyl group substituted with 1 to 3 halogens, and more specifically R¹ is a C1 to C3 alkyl group substituted with at least one of fluoro (—F), iodo (—I), a fluoromethyl group, or an iodomethyl group.

When R¹ is an alkyl group having 4 or more carbon atoms, a non-volatile material due to increases in molecular weight and boiling point may remain for a relatively long time during pattern formation, causing non-uniformity of the coating layer, and the material remaining after exposure may form contaminants such as scum to deteriorate pattern-forming ability.

In an embodiment, R¹ may be a fluoromethyl group, a difluoromethyl group, a trifluoromethyl group, a 1-fluoroethyl group, a 2-fluoroethyl group, a 1,1-difluoroethyl group, a 2,2-difluoroethyl group, a 1,2-difluoroethyl group, a 1,1,2-trifluoroethyl group, a 1,2,2-trifluoroethyl group, an iodomethyl group, a diiodomethyl group, a triiodomethyl group, a 1-iodoethyl group, a 2-iodoethyl group, a 1,1-diiodoethyl group, a 2,2-diiodoethyl group, a 1,2-diiodoethyl group, a 1,1,2-triiodoethyl group, a 1,2,2-triiodoethyl group, a fluoroiodomethyl group, a fluorophenyl group, a difluorophenyl group, a trifluorophenyl group, an iodophenyl group, a diiodophenyl group, a triiodophenyl group, a fluoromethylphenyl group, a difluoromethylphenyl group, a trifluoromethylphenyl group, an iodomethylphenyl group, a diiodomethylphenyl group, or a triiodomethylphenyl group.

In a specific embodiment, the additive represented by Chemical Formula 1 may be selected from compounds listed in Group 1.

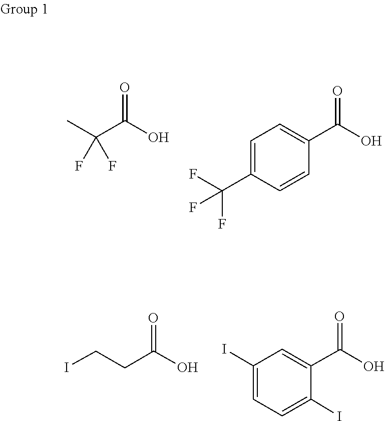

The additive may be included in an amount of about 0.5 wt % to about 10 wt %.

For example, the additive may be included in an amount of about 1.0 wt % to about 10 wt %, about 2.0 wt % to about 8.0 wt %, or about 2.0 wt % to about 6.0 wt %.

The semiconductor photoresist composition may include the additive in an amount of about 0.5 wt % to about 10 wt %, for example, about 1.0 wt % to about 10 wt %, for example, about 2.0 wt % to about 10 wt %, about 2.0 wt % to about 8 wt %, for example, about 2.0 wt % to about 6 wt % based on 100 wt % of the semiconductor photoresist composition. When the additive is included in the above amount, sensitivity and resolution may be further improved.

In other words, the semiconductor photoresist composition according to an embodiment may include about 90 wt % to about 99.5 wt % of the organometallic compound and about 0.1 wt % to about 10 wt % of the additive, and specifically, about 92 wt % to about 98 wt % of the organometallic compound and about 2 wt % to about 8 wt % of the additive, or about 94 wt % to about 98 wt % of the organometallic compound and about 2 wt % to about 6 wt % of the additive.

In the organometallic compound, because the metal strongly absorbs extreme ultraviolet light at about 13.5 nm, the organometallic compound including the metal may have excellent or suitable sensitivity to light having high energy, and thus, the organometallic compound according to an embodiment may exhibit superior stability and sensitivity compared to other organic and/or inorganic resists.

In some embodiments, the organometallic compound may be, for example, an organotin compound.

The organotin compound may include at least one of an alkyl tin oxo group and an alkyl tin carboxyl group.

For example, the organotin compound may be represented by Chemical Formula 2.

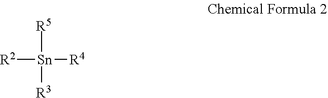

In Chemical Formula 2,

R² is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, and —R^{a}—O—R^{b} (wherein R^{a} is a substituted or unsubstituted C1 to C20 alkylene group and R^{b} is a substituted or unsubstituted C1 to C20 alkyl group),

R³ to R⁵ may each independently be —OR^{c} or —OC(═O)R^{d},

R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

The semiconductor photoresist composition according to an embodiment may further include at least one of an organotin compound represented by Chemical

Formula 3 and an organotin compound represented by Chemical Formula 4 together with the organotin compound represented by Chemical Formula 2.

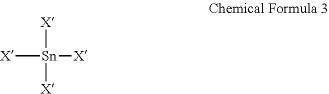

In Chemical Formula 3,

X′is —OR⁶ or —OC(═O)R⁷,

R⁶ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

R⁷ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;

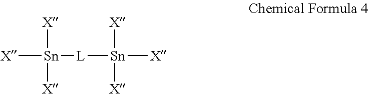

wherein, in Chemical Formula 4,

X″ is —OR⁸ or —OC(═O)R⁹,

R⁸ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,

R⁹ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

L is a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group having at least one double bond or triple bond, a substituted or unsubstituted divalent C6 to C20 aromatic hydrocarbon group, —O—, —C(═O)—, or a combination thereof.

The semiconductor photoresist composition according to an embodiment of the present disclosure includes an organotin compound, the aforementioned additive represented by Chemical Formula 1, an organotin compound represented by Chemical Formula 3, and/or an organotin compound represented by Chemical Formula 4 at the same time and accordingly, a semiconductor photoresist composition having excellent or suitable sensitivity and pattern-forming ability may be provided.

By appropriately adjusting a ratio of the organotin compound represented by Chemical Formula 3 or the organotin compound represented by Chemical Formula 4, it may control a degree of dissociation of the ligand from the copolymer, and accordingly, it may control a degree of crosslinking through oxo bonding with surrounding (e.g., around) chains by radicals generated as the ligand is dissociated to provide a semiconductor photoresist having excellent or suitable sensitivity and resolution. For example, a semiconductor photoresist having excellent or suitable coating properties, sensitivity, and pattern-forming ability may be provided by concurrently (e.g., simultaneously) including the organotin compound represented by Chemical Formula 2, the organotin compound represented by Chemical Formula 3, or the organotin compound represented by Chemical Formula 4.

For example, a total amount of the organotin compound represented by Chemical Formula 3 and the organotin compound represented by Chemical Formula 4, and the organotin compound represented by Chemical Formula 2 may be included in a weight ratio of about 1:1 to about 1:20, for example, about 1:1 to about 1:19, for example, about 1:1 to about 1:18, for example, about 1:1 to about 1:17, for example, about 1:1 to about 1:16, for example, about 1:1 to about 1:15, for example, about 1:1 to about 1:14, for example, about 1:1 to about 1:13, for example, about 1:1 to about 1:12, for example, about 1:1 to about 1:11, for example, about 1:1 to about 1:10, for example, about 1:1 to about 1:9, for example, about 1:1 to about 1:8, for example, about 1:1 to about 1:7, for example, about 1:1 to about 1:6, for example, about 1:1 to about 1:5, for example, about 1:1 to about 1:4, for example, about 1:1 to about 1:3, for example, about 1:1 to about 1:2, but the weight ratio is not limited thereto. When the weight ratio of the organotin compound represented by Chemical Formula 2, the organotin compound represented by Chemical Formula 3, the organotin compound represented by Chemical Formula 4, or a combination thereof satisfies the above range, a semiconductor photoresist composition having excellent or suitable sensitivity and resolution may be provided.

R² of the compound represented by Chemical Formula 2 may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and may be, for example, hydrogen, a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

The organotin compound represented by Chemical Formula 2 may be represented by at least one of Chemical Formula 5 to Chemical Formula 8.

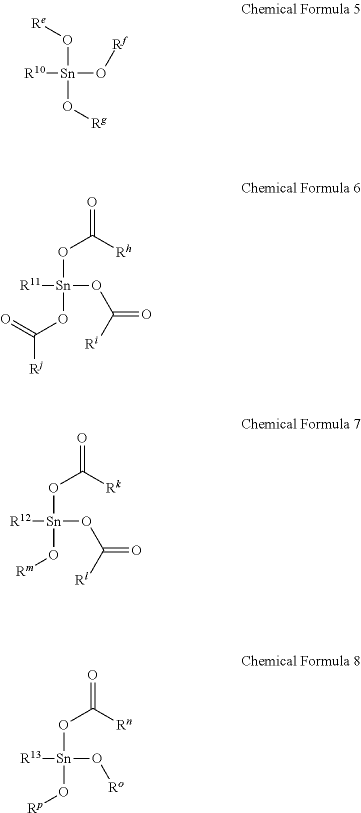

In Chemical Formula 5 to Chemical Formula 8,

R¹⁰ to R¹³ may each independently be a substituted or unsubstituted C1 to C20 alkyl group, a substituted or unsubstituted C3 to C20 cycloalkyl group, a substituted or unsubstituted C2 to C20 aliphatic unsaturated organic group having at least one double bond or triple bond, a substituted or unsubstituted C6 to C30 aryl group, an ethoxy group, a propoxy group, or a combination thereof,

R^{e}, R^{f}, R^{g}, R^{m}, R⁰, and RP may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

R^{h}, Rⁱ, R^{j}, R^{k}, R^{l}, and Rⁿ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In the semiconductor photoresist composition according to an embodiment, the organotin compound represented by Chemical Formula 2 may be included in an amount of about 1 wt % to about 30 wt %, for example, about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, based on 100 wt % of the semiconductor photoresist composition, but the amount thereof is not limited thereto. When the organotin compound represented by Chemical Formula 2 is included in an amount within the above range, storage stability and etch resistance of the semiconductor photoresist composition are improved, and resolution characteristics are improved. The solvent included in the semiconductor resist composition according to

an embodiment may be an organic solvent, and for example, one or more aromatic compounds (e.g., xylene, toluene, etc.), alcohols (e.g., 4-methyl-2-pentenol, 4-methyl-2-propanol, 1-butanol, methanol, isopropyl alcohol, 1-propanol, etc.), ethers (e.g., anisole, tetrahydrofuran, etc.), esters (n-butyl acetate, propylene glycol monomethyl ether acetate, ethyl acetate, ethyl lactate, etc.), ketones (e.g., methyl ethyl ketone, 2-heptanone, etc.), or a mixture thereof, but the present disclosure is not limited thereto.

In an embodiment, the semiconductor resist composition may further include a resin in addition to the organotin compound, the additive represented by Chemical Formula 1, and the solvent.

The resin may be a phenolic resin including at least one of the aromatic moieties listed in Group 2.

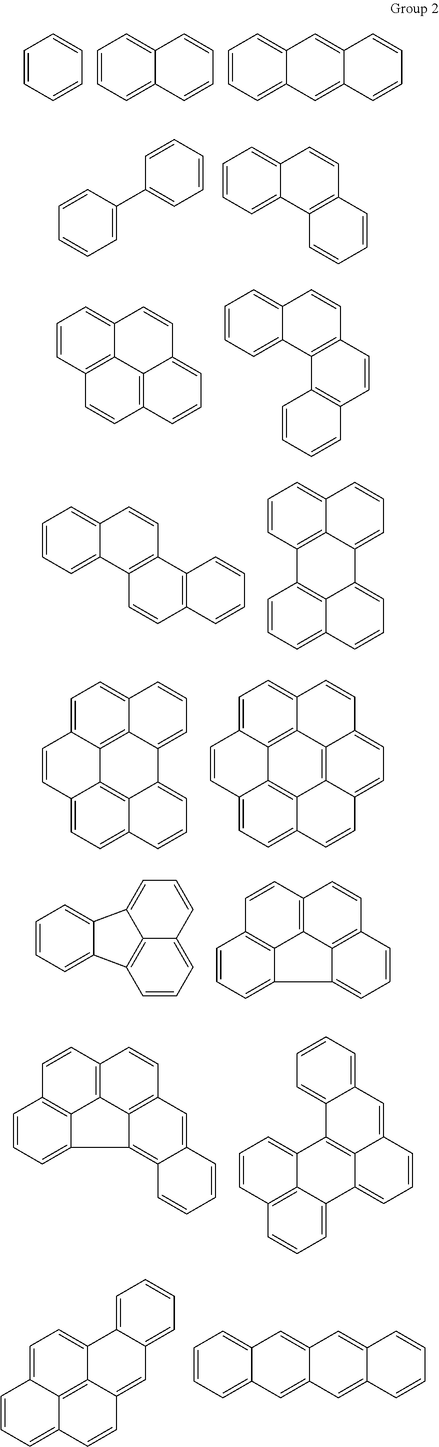

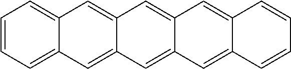 [SMILES: c1ccc2cc3cc4cc5ccccc5cc4cc3cc2c1]

The resin may have a weight average molecular weight of about 500 to about 20,000.

The resin may be included in an amount of about 0.1 wt % to about 50 wt % based on a total amount of the semiconductor resist composition.

When the resin is included within the amount range, it may have excellent or suitable etch resistance and heat resistance.

On the other hand, the semiconductor resist composition according to an embodiment is desirably composed of the aforementioned organotin compound, the additive represented by Chemical Formula 1, a solvent, and a resin. However, the semiconductor resist composition according to the above embodiment may further include other additives as needed. Examples of the other additives may include a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, or a polymer-based crosslinking agent, but is not limited thereto. It may be a crosslinking agent having at least two crosslinking-forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be utilized for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl(p-tolyl) amine, methyl diphenyl amine, triphenyl amine, phenylenediamine, naphthylamine, diaminonaphthalene, or a combination thereof.

A use amount of the other additives may be easily adjusted according to desired or suitable physical properties and the additive may not be provided.

In some embodiments, the semiconductor resist composition may further include a silane coupling agent as an adherence enhancer in order to improve a close-contacting force with the substrate (e.g., in order to improve adherence of the semiconductor resist composition to the substrate).

The silane coupling agent may be for example a silane compound including a carbon-carbon unsaturated bond such as vinyltrimethoxysilane, vinyltriethoxysilane, vinyl trichlorosilane, vinyltris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but is not limited thereto.

The semiconductor photoresist composition may be formed into a pattern having a high aspect ratio without collapsing. Accordingly, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, about 5 nm to about 20 nm, or about 5 nm to about 10 nm, the semiconductor photoresist composition may be utilized for a photoresist process utilizing light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to an embodiment may be utilized to realize extreme ultraviolet lithography utilizing an EUV light source of a wavelength of about 13.5 nm.

According to another embodiment, a method of forming patterns utilizing the aforementioned semiconductor photoresist composition is provided. For example, the manufactured pattern may be a photoresist pattern.

The method of forming patterns according to an embodiment includes forming an etching-objective layer on a substrate, coating the semiconductor photoresist composition on the etching-objective layer to form a photoresist layer, patterning the photoresist layer to form a photoresist pattern, and etching the etching-objective layer utilizing the photoresist pattern as an etching mask.

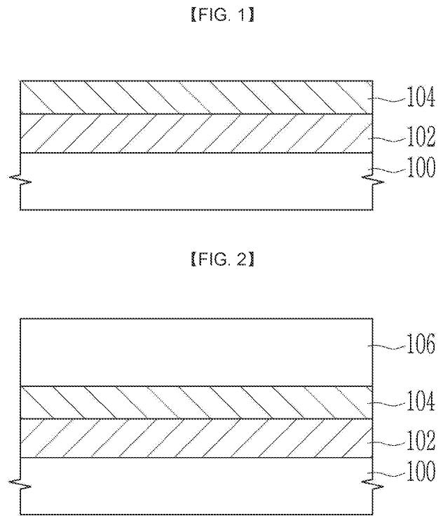

Hereinafter, a method of forming patterns utilizing the semiconductor photoresist composition is described referring to FIGS. 1 to 5. FIGS. 1 to 5 are cross-sectional views for explaining a method of forming patterns utilizing a semiconductor photoresist composition according to an embodiment.

Referring to FIG. 1, an object for etching is prepared. The object for etching

may be a thin film 102 formed on a semiconductor substrate 100. Hereinafter, the thing film 102 is described as the object for etching for convenience. A whole surface of the thin film 102 is washed to remove impurities and/or the like remaining thereon. The thin film 102 may be for example a silicon nitride layer, a polysilicon layer, or a silicon oxide layer.

Subsequently, the resist underlayer composition for forming a resist underlayer 104 is spin-coated on the surface of the washed thin film 102. However, the embodiment is not limited thereto, and one or more suitable coating methods, for example a spray coating, a dip coating, a knife edge coating, a printing method, for example an inkjet printing and a screen printing, and/or the like may be utilized.

The coating process of the resist underlayer may not be provided, and hereinafter, a process including a coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and improve pattern-forming ability of a photoresist line width when a ray reflected from on the interface between the substrate 100 and the photoresist layer 106 or a hardmask between layers is scattered into an unintended photoresist region.

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

More specifically, the formation of a pattern by utilizing the semiconductor photoresist composition may include coating the aforementioned semiconductor photoresist composition on the substrate 100 having the thin film 102 through spin coating, slit coating, inkjet printing, and/or the like and then, drying it to form the photoresist layer 106.

The semiconductor photoresist composition has already been described in more detail and will not be illustrated again.

Subsequently, the substrate 100 having the photoresist layer 106 is subjected to a first baking process. The first baking process may be performed at about 80° C. to about 120° C.

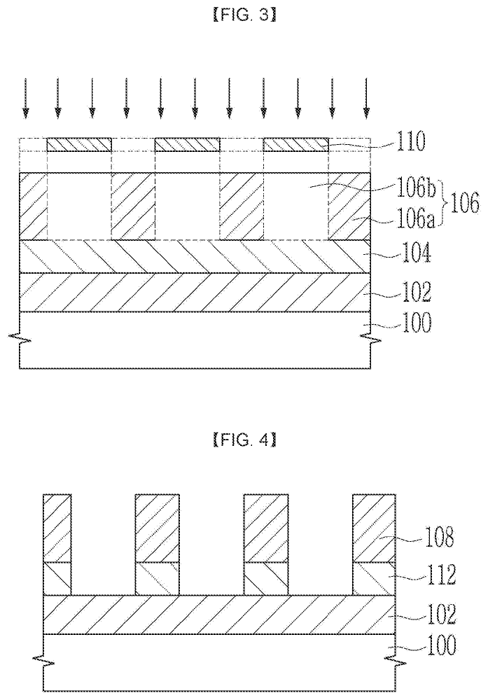

Referring to FIG. 3, the photoresist layer 106 may be selectively exposed.

For example, the exposure may utilize an activation radiation with light having a high energy wavelength such as EUV (extreme ultraviolet; a wavelength of about 13.5 nm), an E-Beam (an electron beam), and/or the like as well as a short wavelength such as an i-line (a wavelength of about 365 nm), a KrF excimer laser (a wavelength of about 248 nm), an ArF excimer laser (a wavelength of about 193 nm), and/or the like.

More specifically, light for the exposure according to an embodiment may have a short wavelength in a range of about 5 nm to about 150 nm and a high energy wavelength, for example, EUV (Extreme UltraViolet; a wavelength of about 13.5 nm), an E-Beam (an electron beam), and/or the like.

The exposed region 106a of the photoresist layer 106 has a different solubility from the non-exposed region 106b of the photoresist layer 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106a of the photoresist layer 106 becomes easily indissoluble (e.g., not easily dissolvable) regarding a developing solution due to the second baking process.

In FIG. 4, the non-exposed region 106b of the photoresist layer is dissolved and removed utilizing the developing solution to form a photoresist pattern 108. For example, the non-exposed region 106b of the photoresist layer is dissolved and removed by utilizing an organic solvent such as 2-heptanone and/or the like to complete the photoresist pattern 108 corresponding to the negative tone image.

As described above, a developing solution utilized in a method of forming patterns according to an embodiment may be an organic solvent. The organic solvent utilized in the method of forming patterns according to an embodiment may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to an embodiment is not necessarily limited to the negative tone image but may be formed to have a positive tone image. Herein, a developing agent utilized for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (Extreme UltraViolet; a wavelength of about 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width (e.g., width of a thickness) of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

On the other hand, the photoresist pattern 108 may have a pitch of having a half-pitch of less than or equal to about 50 nm, for example, less than or equal to about 40 nm, for example, less than or equal to about 30 nm, for example, less than or equal to about 20 nm, or for example less than or equal to about 10 nm and a line width roughness of less than or equal to about 10 nm, less than or equal to about 5 nm, less than or equal to about 3 nm, less than or equal to about 2 nm, or less than or equal to about 1 nm.

Subsequently, the photoresist pattern 108 is utilized as an etching mask to etch the resist underlayer 104. Through this etching process, an organic layer pattern 112 is formed. The organic layer pattern 112 also may have a width corresponding to that of the photoresist pattern 108.

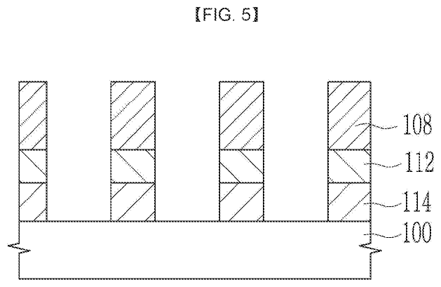

Referring to FIG. 5, the photoresist pattern 108 is applied as an etching mask to etch the exposed thin film 102. As a result, the thin film is formed with a thin film pattern 114.

The etching of the thin film 102 may be for example dry etching utilizing an etching gas and the etching gas may be for example CHF₃, CF₄, Cl₂, BCl₃ and a mixed gas thereof.

In the exposure process, the thin film pattern 114 formed by utilizing the photoresist pattern 108 formed through the exposure process performed by utilizing an EUV light source may have a width corresponding to that of the photoresist pattern 108. For example, the thin film pattern 114 may have a width of about 5 nm to about 100 nm which is (e.g., substantially) equal to that of the photoresist pattern 108. For example, the thin film pattern 114 formed by utilizing the photoresist pattern 108 formed through the exposure process performed by utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or less than or equal to about 20 nm.

Hereinafter, the present disclosure will be described in more detail through examples of the preparation of the aforementioned semiconductor photoresist composition. However, the technical features of the present disclosure are not limited by the following examples.

### Synthesis of Organotin Compounds

### Synthesis Example 1

20 g (51.9 mmol) of Ph₃SnCl was dissolved in 70 mL of THF in a 250 mL 2-necked and round-bottomed flask and then, cooled down to 0° C. in an ice bath. Subsequently, a 1 M butyl magnesium chloride (BuMgCl) THE solution (62.3 mmol) was slowly added thereto in a dropwise fashion. When the addition in a dropwise fashion was complete, the obtained mixture was stirred at 25° C. for 12 hours to obtain a compound represented by Chemical Formula 9a.

Then, the compound represented by Chemical Formula 9a (10 g, 24.6 mmol) was dissolved in 50 mL of CH2Cl2, and 3 equivalents (73.7 mmol) of a 2 M HCl diethyl ether solution was slowly added thereto in a dropwise fashion at -78° C. for 30 minutes. Subsequently, the obtained mixture was stirred at 25° C. for 12 hours, and then, a compound represented by Chemical Formula 9b was obtained by concentrating the solvent and performing vacuum distillation.

Thereafter, 25 mL of acetic acid was slowly added in a dropwise fashion to 10 g (25.6 mmol) of the compound of Chemical Formula 9b at 25° C., followed by heating under reflux for 12 hours. The temperature is increased to 25° C., and then, acetic acid was vacuum-distilled to obtain a compound represented by Chemical Formula 9.

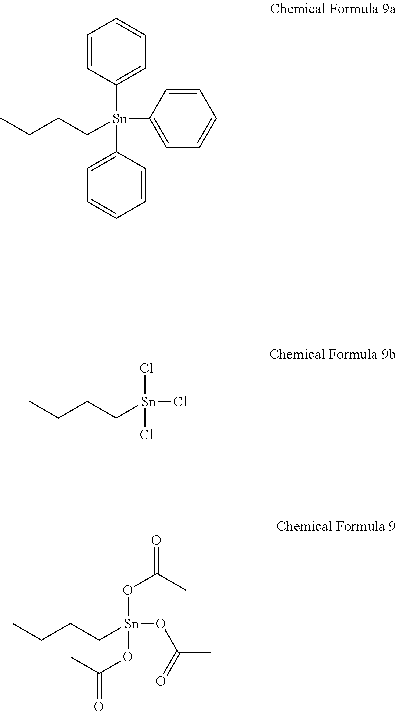

### Preparation of Semiconductor Photoresist Compositions

### Examples 1 to 4 and Comparative Examples 1 to 5

Each semiconductor photoresist composition was prepared by dissolving the compound represented by Chemical Formula 9 according to Synthesis Example 1 and each additive in propylene glycol methyl ether acetate at a solid content (e.g., amount) of 3 wt % according to a composition shown in Table 1 and filtering each solution with a 0.1 μm PTFE (polytetrafluoroethylene) syringe filter.

### Formation of Photoresist Layer

A circular silicon wafer with a native-oxide surface and a diameter of 4 inches was utilized as a substrate for depositing a thin film and treated in a UV ozone cleaning system for 10 minutes before depositing the thin film. On the treated substrate, the semiconductor photoresist compositions according to Examples 1 to 4 and Comparative Examples 1 to 5 were respectively spin-coated at 1500 rpm for 30 seconds and post-apply baked (PAB) at 110° C. for 60 seconds, forming thin films.

Subsequently, the thin films were measured with respect to a thickness after the coating and the baking through ellipsometry, and the result was 25 nm.

TABLE 1

| | Organotin compound (wt %) | Additive (wt %) |
|---|---|---|
| Example 1 | Chemical Formula 9 (95) | 2,2-difluoropropionic acid (5) |
| Example 2 | Chemical Formula 9 (95) | 3-iodopropionic acid (5) |
| Example 3 | Chemical Formula 9 (95) | 2,5-diiodobenzoic acid (5) |
| Example 4 | Chemical Formula 9 (95) | 4-(trifluoromethyl)benzoic acid (5) |
| Comparative | Chemical Formula 9 (95) | — |
| Example 1 | | |
| Comparative | Chemical Formula 9 (95) | 1-adamantane carboxylic acid (5) |
| Example 2 | | |
| Comparative | Chemical Formula 9 (95) | propionic acid (5) |
| Example 3 | | |
| Comparative | Chemical Formula 9 (95) | glycolic acid (5) |
| Example 4 | | |
| Comparative | Chemical Formula 9 (95) | 5,5,5-trifluoropentanoic acid (5) |
| Example 5 | | |

### Evaluation 1: Coating Properties

The photoresist layers prepared in the coating method according to Examples 1 to 4 and Comparative Examples 1 to 5 were measured with respect to surface roughness (Rq) through AFM (atomic force microscopy), and the results are shown in Table 2.

### Evaluation 2: Sensitivity

The wafers respectively coated with the photoresist compositions Examples 1 to 4 and Comparative Examples 1 to 5 were irradiated by varying an exposure dose of EUV light (Lawrence Berkeley National Laboratory Micro Exposure Tool, MET).

Subsequently, the resists and the substrates were post-exposure baked (PEB) on a hot plate at 160° C. for 120 seconds. The baked films were respectively dipped in a developing solution (2-heptanone) for 30 seconds and additionally, washed with the same developer for 10 seconds to form a negative tone image, that is, an unexposed coating portion. Finally, the exposed films were baked on a hot plate at 150° C. for 2 minutes, forming a L/S pattern of 1:1.

After measuring Eop capable of implementing a pattern with a desired or suitable line width of 14 nm in the L/S pattern by utilizing an electron microscope (FE-SEM), the results are shown in Table 2.

TABLE 2

| | Rq (nm) | Eop (mJ/cm²) |
|---|---|---|
| Example 1 | 0.36 | 173 |
| Example 2 | 0.35 | 178 |
| Example 3 | 0.36 | 185 |
| Example 4 | 0.35 | 175 |
| Comparative Example 1 | 2.16 | 320 |
| Comparative Example 2 | 0.52 | 221 |
| Comparative Example 3 | 1.97 | 304 |
| Comparative Example 4 | 0.45 | 193 |
| Comparative Example 5 | 1.86 | 215 |

Referring to the results of Table 2, the photoresist compositions for a semiconductor according to Examples 1 to 4 exhibited much more excellent or suitable coating properties and sensitivity, compared with the photoresist composition for a semiconductor including no additive according to Comparative Example 1 and the photoresist compositions for a semiconductor utilizing an additive not belonging to Chemical Formula 1 of the present disclosure according to Comparative Examples 2 to 5.

Hereinbefore, the certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

Description of Symbols

| | |
|---|---|
| 100: substrate | 102: thin film |
| 104: resist underlayer | 106: photoresist layer |
| 106a: exposed region | 106b: non-exposed region |
| 108: photoresist pattern | 112: organic layer pattern |
| 110: patterned hardmask | 114: thin film pattern |

What is claimed is:

1. A semiconductor photoresist composition, comprising
an organometallic compound;
an additive represented by Chemical Formula 1; and
a solvent: 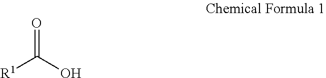
wherein, in Chemical Formula 1,
R¹ is a C1 to C12 alkyl group substituted with at least one halogen, a C3 to C10 cycloalkyl group substituted with at least one halogen, a C6 to C20 aryl group substituted with at least one halogen, a C3 to C10 cycloalkyl group substituted with at least one C1 to C5 haloalkyl group substituted with at least one halogen, a C6 to C20 aryl group substituted with at least one C1 to C5 haloalkyl group substituted with at least one halogen, or a combination thereof.

2. The semiconductor photoresist composition of claim 1, wherein
R¹ is a C1 to C12 alkyl group substituted with 1 to 3 halogens, a C3 to C10 cycloalkyl group substituted with 1 to 3 halogens, a C6 to C20 aryl group substituted with 1 to 3 halogens, a C3 to C10 cycloalkyl group substituted with a C1 to C5 haloalkyl group substituted with 1 to 3 halogens, a C6 to C20 aryl group substituted with a C1 to C5 haloalkyl group substituted with 1 to 3 halogens, or a combination thereof.

3. The semiconductor photoresist composition of claim 1, wherein
R¹ is:
a C1 to C7 alkyl group substituted with at least one of fluoro (—F), iodo (—I), a C1 to C5 fluoroalkyl group, or a C1 to C5 iodoalkyl group;
A C3 to C10 cycloalkyl group substituted with at least one of fluoro (—F), iodo (—I), a C1 to C5 fluoroalkyl group, or a C1 to C5 iodoalkyl group;
a C6 to C20 aryl group substituted with at least one of fluoro (—F), iodo (—I), a C1 to C5 fluoroalkyl group, or a C1 to C5 iodoalkyl group; or
a combination thereof.

4. The semiconductor photoresist composition of claim 1, wherein
R¹ is:
a C1 to C3 alkyl group substituted with at least one of fluoro (—F), iodo (—I), a fluoromethyl group, or an iodomethyl group;
a C3 to C6 cycloalkyl group substituted with at least one of fluoro (—F), iodo (—I), a fluoromethyl group, or an iodomethyl group;
a C6 to C12 aryl group substituted with at least one of fluoro (—F), iodo (—I), a fluoromethyl group, or an iodomethyl group; or
a combination thereof.

5. The semiconductor photoresist composition of claim 1, wherein
R¹ is a fluoromethyl group, a difluoromethyl group, a trifluoromethyl group, a 1-fluoroethyl group, a 2-fluoroethyl group, a 1,1-difluoroethyl group, a 2,2-difluoroethyl group, a 1,2-difluoroethyl group, 1,1,2-trifluoroethyl group, a 1,2,2-trifluoroethyl group, an iodomethyl group, a diiodomethyl group, a triiodomethyl group, a 1-iodoethyl group, a 2-iodoethyl group, a 1,1-diiodoethyl group, a 2,2-diiodoethyl group, a 1,2-diiodoethyl group, a 1,1,2-triiodoethyl group, a 1,2,2-triiodoethyl group, a fluoroiodomethyl group, a fluorophenyl group, a difluorophenyl group, a trifluorophenyl group, an iodophenyl group, a diiodophenyl group, a triiodophenyl group, a fluoromethylphenyl group, a difluoromethylphenyl group, a trifluoromethylphenyl group, an iodomethylphenyl group, a diiodomethylphenyl group, or a triiodomethylphenyl group.

6. The semiconductor photoresist composition of claim 1, wherein
the additive represented by Chemical Formula 1 is selected from among compounds listed in Group 1:

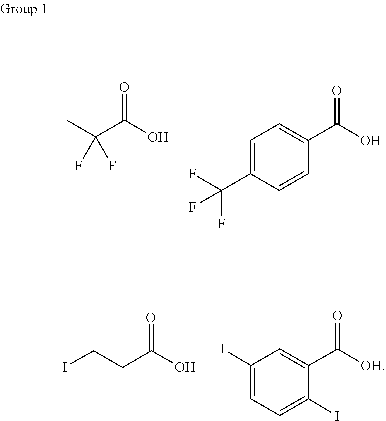

7. The semiconductor photoresist composition of claim 1, wherein
the additive is included at about 0.5 wt % to about 10 wt %.

8. The semiconductor photoresist composition of claim 1, wherein
the organometallic compound is an organotin compound.

9. The semiconductor photoresist composition of claim 8, wherein
the organotin compound comprises at least one of an alkyl tin oxo group or an alkyl tin carboxyl group.

10. The semiconductor photoresist composition of claim 8 , wherein
the organotin compound is represented by Chemical Formula 2: 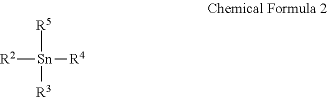
wherein, in Chemical Formula 2,
R² is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),
R³ to R⁵ are each independently —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

11. The semiconductor photoresist composition of claim 10, wherein
at least one of an organotin compound represented by Chemical Formula 3 or an organotin compound represented by Chemical Formula 4 is further included: 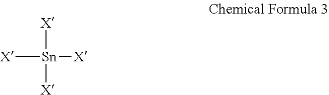
wherein, in Chemical Formula 3,
X′ is —OR6 or —OC(═O)R⁷,
R⁶ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R⁷ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; 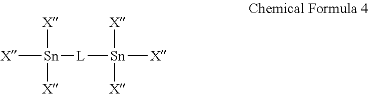
wherein, in Chemical Formula 4,
X″ is —OR⁸ or —OC(═O)R⁹,
R⁸ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R⁹ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
L is a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group having at least one double bond or triple bond, a substituted or unsubstituted divalent C6 to C20 aromatic hydrocarbon group, —O—, —C(═O)—, or a combination thereof.

12. The semiconductor photoresist composition of claim 11, wherein
a total amount of the organotin compound represented by Chemical Formula 3 and the organotin compound represented by Chemical Formula 4, and
the organotin compound represented by Chemical Formula 2,
is included in a weight ratio of about 1:1 to about 1:20.

13. The semiconductor photoresist composition of claim 10, wherein
the organotin compound represented by Chemical Formula 2 is represented by at least one selected from among Chemical Formula 5 to Chemical Formula 8: 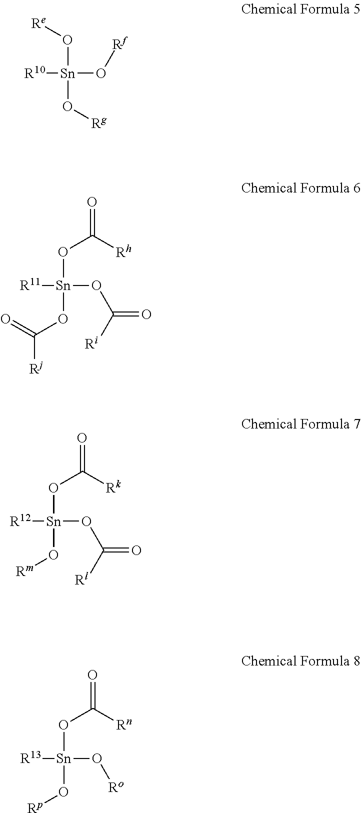
wherein, in Chemical Formula 5 to Chemical Formula 8,
R¹⁰ to R¹³ are each independently a substituted or unsubstituted C1 to C20 alkyl group, a substituted or unsubstituted C3 to C20 cycloalkyl group, a substituted or unsubstituted C2 to C20 aliphatic unsaturated organic group having at least one double bond or triple bond, a substituted or unsubstituted C6 to C30 aryl group, an ethoxy group, a propoxy group, or a combination thereof,
R^{e}, R^{f}, R^{g}, R^{m}, R^{o}, and R^{p} are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{h}, Rⁱ, R^{j}, R^{k}, R^{l}, and Rⁿ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

14. The semiconductor photoresist composition of claim 1, wherein
the semiconductor photoresist composition further comprises an additive of a surfactant, a crosslinking agent, a leveling agent, or a combination thereof.

15. A method of forming patterns, the method comprising
applying an etching-objective layer on a substrate,
coating the semiconductor photoresist composition of claim 1 on the etching-objective layer to form a photoresist layer,
patterning the photoresist layer to form a photoresist pattern, and
etching the etching-objective layer utilizing the photoresist pattern as an etching mask.

16. The method of claim 15, wherein
the photoresist pattern is patterned utilizing light in a wavelength of about 5 nm to about 150 nm.

17. The method of claim 15, wherein
the method further comprises applying a resist underlayer between the substrate and the photoresist layer.

18. The method of claim 15, wherein
the photoresist pattern has a width of about 5 nm to about 100 nm.
